(19) United States
(12) Patent Application Publication
(10) Pub. No.: US 2024/0183922 A1
(43) Pub. Date: Jun. 6, 2024

(54) COMPACT SIGNAL FEATURE EXTRACTION FROM MULTI-CONTRAST MAGNETIC RESONANCE IMAGES USING SUBSPACE RECONSTRUCTION

(71) Applicant: The General Hospital Corporation, Boston, MA (US)

(72) Inventors: Kawin Setsompop, Stanford, CA (US); Zijing Dong, Cambridge, MA (US); Fuyixue Wang, Cambridge, MA (US)

(21) Appl. No.: 18/552,972

(22) PCT Filed: Mar. 28, 2022
(86) PCT No.: PCT/US2022/022121

§ 371 Date: Sep. 28, 2023

Related U.S. Application Data
(60) Provisional application No. 63/167,089, filed on Mar. 28, 2021.

(51) Int. Cl. G01R 33/56; G06T 7/00

(52) U.S. Cl. CPC G01R 33/5608; G01R 33/5602; G06T 7/0012; G06T 2207/10088; G06T 2207/20081; G06T 2207/30024

(57) ABSTRACT

Signal feature data are efficiently extracted from multi-contrast magnetic resonance images and applied to one or more machine learning algorithms to generate tissue feature data that indicate one or more tissue properties of a tissue depicted in the original multi-contrast images. Compact signal feature map data are extracted from the multi-contrast image data by generating or otherwise constructing subspace bases from prior signal data. and coefficient maps of the subspace bases are generated using a subspace reconstruction. A machine learning algorithm can be implemented to transform the signal feature maps to target tissue property parameters and/or to classify different tissue types.

### STATEMENT OF FEDERALLY SPONSORED RESEARCH

This invention was made with government support under EB020613 and EB025162 awarded by the National Institutes of Health. The government has certain rights in the invention.

### BACKGROUND

Magnetic resonance imaging (“MRI”) can acquire images that contain rich information related to various tissue properties, and has become an important tool in both clinical use and neuroscience research. Magnetic resonance images with different contrasts (e.g., T1-weighted images, T2-weighted images, fluid attenuation inversion recovery (“FLAIR”) images) are sensitive to different tissues properties; thus, multiple pulse sequences have been developed to acquire different image contrasts to assess different pathological changes of tissue. In addition to conventional single-contrast acquisitions, multi-contrast and quantitative mapping techniques have been developed that usually acquire more signals to better probe the tissue properties and calculate quantitative metrics. For example, echo-planar time-resolved imaging (“EPTI”) is a technique that can acquire hundreds to thousands of multi-contrast images to track the signal evolution and fit quantitative maps. Although these multi-contrast acquisition techniques provide image series with rich information, it is difficult to directly interpret the massive dataset acquired with these techniques. Therefore, an effective method to extract the useful information from the large datasets images would be helpful in clinical practice.

Currently, one common method is estimating quantitative parameters from the acquired image series based on some known signal models (e.g., T1, T2 signal model) such as in so-called magnetic resonance fingerprinting (“MRF”) techniques. However, the simplified model typically does not fully represent the original signal evolution. For example, traditional T1/T2 models ignore magnetization transfer and multi-compartment effects, which might otherwise be helpful to detect/diagnose changes in tissue.

Another method to extract information from multi-contrast images is to train a machine learning algorithm to learn the relationship between the images and target tissue properties to classify or detect different types of tissue. Many learning or clustering based methods have been developed for disease diagnosis using MRI, but are mainly focused on using several clinical-routine image contrasts (e.g., T1-weighted images, T2-weighted images, FLAIR). Hence, there is still lack of an effective method to extract accurate tissue properties and diagnosis information from massive image datasets (e.g., greater than 100 or even 1000 images) acquired using imaging techniques such as EPTI and other spatiotemporal acquisitions.

### SUMMARY OF THE DISCLOSURE

The present disclosure addresses the aforementioned drawbacks by providing a method for generating compact signal feature maps from multi-contrast magnetic resonance images. The method includes accessing multi-contrast image data with a computer system, where the multi-contrast image data include a plurality of magnetic resonance images acquired with a magnetic resonance imaging (“MRI”) system from a subject. The plurality of magnetic resonance images depict multiple different contrast weightings. Subspace bases are generated from prior signal data using the computer system, and coefficient maps for the subspace bases are reconstructed using a subspace reconstruction framework implemented with the computer system. The subspace reconstruction framework takes as inputs the subspace bases and the multi-contrast image data. The coefficient maps are stored as compact signal feature data using the computer system, where the compact signal feature data depict similar information as the multi-contrast image data with significantly reduced degrees of freedom relative to the multi-contrast image data.

The foregoing and other aspects and advantages of the present disclosure will appear from the following description. In the description, reference is made to the accompanying drawings that form a part hereof, and in which there is shown by way of illustration one or more embodiments. These embodiments do not necessarily represent the full scope of the invention, however, and reference is therefore made to the claims and herein for interpreting the scope of the invention.

### BRIEF DESCRIPTION OF THE DRAWINGS

FIG. 1 is a flowchart illustrating the steps of an example method for generating compact signal feature map data from multi-contrast magnetic resonance image data using a subspace bases extraction and reconstruction process.

FIG. 2 illustrates an example of generating subspace bases from prior signal data.

FIG. 3 is a flowchart illustrating the steps of an example method for generating tissue feature data by applying compact signal feature map data to a suitably trained machine learning algorithm.

FIG. 4 is a flowchart illustrating the steps of an example method for training a machine learning algorithm to generate tissue feature data from compact signal feature data.

FIG. 5 is a block diagram of an example magnetic resonance imaging (“MRI”) system that can implement the methods described in the present disclosure.

FIG. 6 is a block diagram of an example system for extracting compact signal feature map data from multi-contrast magnetic resonance image data and for characterizing tissues based on the compact signal feature map data.

FIG. 7 is a block diagram of example components that can implement the system of FIG. 6.

### DETAILED DESCRIPTION

Described here are systems and methods for efficiently extracting signal feature data from multi-contrast magnetic resonance images. A processing framework is provided to efficiently extract target information from a multi-contrast image series. The framework implemented by the systems and methods described in the present disclosure include two general components: a signal feature map (or signal feature data) extraction process and a machine transformation for transforming the feature maps to target tissue property parameters and/or to classify different tissue types.

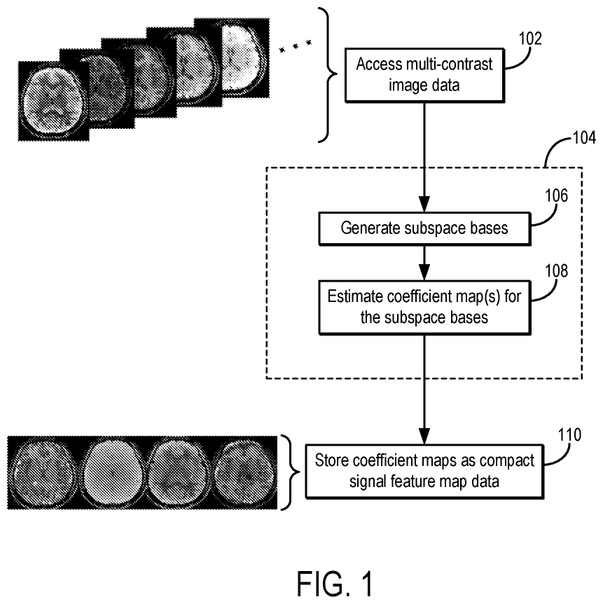

Referring now to FIG. 1, a flowchart is illustrated as setting forth the steps of an example method for generating compact signal feature data from a large multi-contrast image dataset. Compact signal feature maps are extracted from multi-contrast images. These compact signal feature maps contain the same, or similar, information as the original multi-contrast images, but with significantly reduced size of the data. The extracted signal feature maps can be used as input to machine learning algorithms or other image analysis frameworks. Different machine learning algorithms can be used, for example, to transform the compact signal feature maps to target tissue property maps or to detect different types of pathological change.

The method includes accessing multi-contrast image data with a computer system, as indicated at step 102. Accessing the multi-contrast image data can include retrieving previously acquired data from a memory or other data storage device or medium. In some embodiments, the multi-contrast data can be retrieved from a database, server, or other data archive, such as a picture archiving and communication system (“PACS”). Additionally or alternatively, accessing the multi-contrast image data can include acquiring the data with an MRI system and communicating the data to the computer system, which may be a part of the MRI system.

As a non-limiting example, the multi-contrast image data can include multi-contrast magnetic resonance images. For instance, the multi-contrast image data can include a series of images acquired with different contrast weightings (e.g., T1-weighitng, T2-weighting, T2*-weighting, fluid attenuation inversion recovery (“FLAIR”), etc.). In some embodiments, the multi-contrast image data can be acquired using a spatiotemporal acquisition scheme, such as EPTI. Additionally or alternatively, the multi-contrast image data can include k-space data, k-t space, or the like.

From the multi-contrast image data, compact signal feature maps, or other signal feature data, are extracted, as indicated at step 104. As a non-limiting example, an extraction operation is applied to the multi-contrast image series to calculate signal feature maps that can fully represent the original image series with some prior information.

An example operation that can be used when extracting the signal feature maps is projecting the signal series to a group of temporal subspace bases, and use the coefficient maps of the subspace bases as signal feature maps. Thus, in some examples, one or more subspace bases are generated or otherwise constructed, as indicated at substep 106. As a non-limiting example, subspace bases can be generated from prior signal data, which can be previously acquired signal data, simulated signal data, or the like. For instance, in some embodiments the prior signal data can include prior magnetic resonance image data acquired with an MRI system in a previous imaging session. The prior magnetic resonance image data can be acquired from the same subject as the multi-contrast image data accessed in step 102, or can include magnetic resonance image data acquired from one or more different subjects.

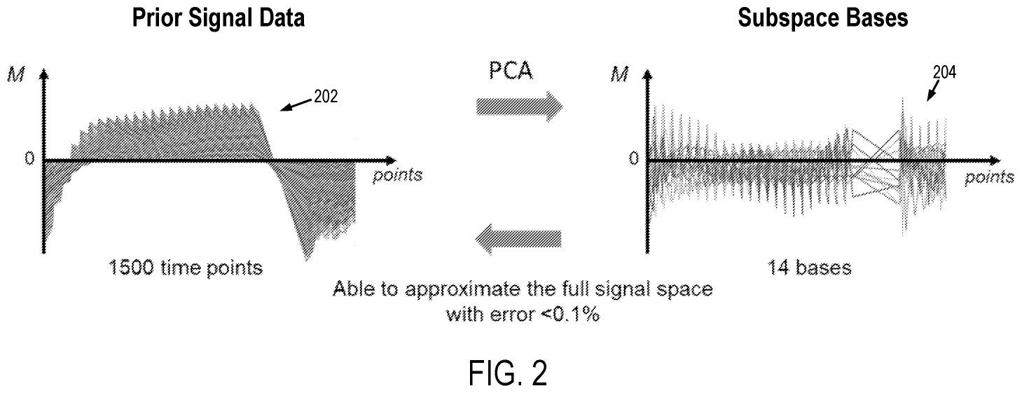

Additionally or alternatively, the prior signal data can include simulated signal data. In these instances, the prior signal data can be extracted, estimated, or otherwise generated from a signal model, such as a signal model based on one or more Bloch equations. For example, the prior signal data can be generated using a principal component analysis (“PCA”) of simulated signal data. FIG. 2 illustrates an example of using PCA to generate subspace bases from the temporal signal evolution in a specific MR acquisition. The signal evolution curves 202 are simulated based on the tissue and acquisition parameters (e.g., acquisition parameters associated with the pulse sequence and other aspects of the data acquisition). The subspace bases 204 are extracted with significantly reduced degrees of freedom (e.g., in the illustrated example the degrees of freedom are reduced from 1500 to 14). Using the compressed bases, the original signal space can still be approximated accurately with very small error. Alternatively, other transform operations can be used for extracting compact maps from the multi-contrast images, such as independent component analysis (“ICA”) and manifold learning.

Advantageously, the signal series space can be approximated accurately by just several subspace bases. Thus, the degrees of freedom of an otherwise massive multi-contrast image dataset can be significantly reduced after projecting the image series to the generated subspace bases. As a non-limiting example, several coefficient maps can be used to accurately represent the original multi-contrast image series. Although the extracted feature maps contain the same or similar information as the original multi-contrast image series, they are much more compact with reduced dimensions. This advantageous characteristic of the extracted feature maps can reduce the complexity of the machine learning aspects for classification and detection as compared to using full image series data as input, while avoiding a compromise on accuracy when compared with using over-simplified quantitative relaxometry parametric maps.

Referring again to FIG. 1, the signal feature maps can be extracted from multi-contrast images after reconstruction, or directly from k-space data, as noted above. As a non-limiting example, a coefficient map of subspace bases can be estimated, as indicated at step 108, using a subspace reconstruction as:

$${min}_{c} {‖ UFSB ϕ c - y ‖}_{2}^{2} + λ R ( c ) ; \qquad ( 1 )$$

where ϕ corresponds to the subspace bases, c are the coefficient maps of the bases, B is the phase evolution across different image echoes due to B₀ inhomogeneity, S is the coil sensitivity, F is the Fourier transform operator, U is the undersampling mask, and y is the acquired undersampled k-space data. The regularization term, R(c), can be incorporated to further improve the conditioning and SNR, and λ is the control parameter of the regularization.

The feature maps (e.g., coefficient maps for the extracted subspace bases) can then be stored for later use, or displayed to a user, as indicated at step 110. For instance, the feature maps can be used to train machine learning algorithms, or can be applied to trained machine learning algorithms to implement different tasks, such as classification of the multi-contrast image data, cluster analysis of the multi-contrast image data, or the like. In general, a machine learning algorithm can be trained or otherwise constructed to learn a relationship between the extracted signal feature maps and one or more target properties of an underlying tissue depicted in the multi-contrast image data, which in some instances may include microstructure of the tissue. The machine learning algorithm(s) can be used to perform computer-assisted diagnosis and analysis using the compact feature maps, which contain rich information from the multi-contrast MR acquisition. As one non-limiting example, a supervised learning-based machine learning algorithm can be used to classify multi-contrast image data based on extracted feature maps. As another non-limiting example, an unsupervised learning-based machine learning algorithm can be used for cluster analysis of the multi-contrast image data.

Overall, the proposed framework combines signal feature map extraction and machine learning-based classification and/or detection, providing an efficient technique to extract compact and accurate information from massive multi-contrast MR image datasets. The extracted signal feature maps reserve the information of the multi-contrast image series, but are much compact with reduced dimensions, which can reduce the complexity of machine learning algorithm(s) for more efficient information extraction and image analysis. Advantageously, these methods can significantly improve the efficiency of machine learning-based image analyses of multi-contrast image datasets.

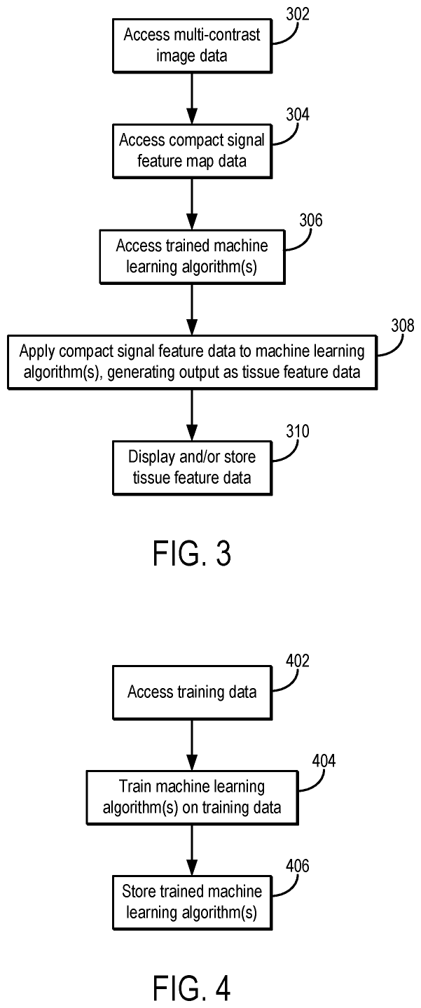

Referring now to FIG. 3, a flowchart is illustrated as setting forth the steps of an example method for estimating tissue feature data (e.g., tissue properties, tissue classifications, lesion classifications) using a suitably trained machine learning algorithm applied to compact signal feature data.

The method includes accessing multi-contrast image data with a computer system, as indicated at step 302. Accessing multi-contrast image data may include retrieving such data from a memory or other suitable data storage device or medium. Alternatively, accessing the multi-contrast image may include acquiring such data with an MRI and transferring or otherwise communicating the data to the computer system, which may be a part of the MRI system.

The method also includes accessing compact signal feature map data with a computer system, as indicated at step 304. Accessing compact signal feature map data may include retrieving such data from a memory or other suitable data storage device or medium. Alternatively, accessing the compact signal feature map data may include extracting or otherwise generating such data from the multi-contrast image data using the computer system. For instance, the method described above with respect to FIG. 1 can be implemented to extract or otherwise generate the compact signal feature map data from the multi-contrast image data.

A trained machine learning algorithm and/or model is then accessed with the computer system, as indicated at step 306. Accessing the machine learning algorithm may include accessing model parameters (e.g., weights, biases, or both) that have been optimized or otherwise estimated by training the machine learning algorithm on training data. In some instances, retrieving the machine learning algorithm can also include retrieving, constructing, or otherwise accessing the particular model architecture to be implemented. For instance, data pertaining to the layers in a neural network architecture (e.g., number of layers, type of layers, ordering of layers, connections between layers, hyperparameters for layers) or other model architecture may be retrieved, selected, constructed, or otherwise accessed.

In general, the machine learning algorithm is trained, or has been trained, on training data in order to classify tissues in the multi-contrast image data, to perform a cluster analysis on the multi-contrast image data, or to otherwise characterize tissue properties or tissue microstructure based on inputting compact signal feature map data to the machine learning algorithm.

In some instances, more than one machine learning algorithm may be accessed. For example, a first machine learning algorithm may have been trained on first training data to classify tissues depicted in multi-contrast image data based on inputting compact signal feature map data to the first machine learning algorithm, and a second machine learning algorithm may have been trained on second training data to estimate one or more tissue properties based on inputting the compact signal feature map data to the second machine learning algorithm.

The compact signal feature map data are then input to the one or more trained machine learning algorithms, generating output as tissue feature data, as indicated at step 308. For example, the tissue feature data may include feature maps associated with estimated tissue properties of tissue depicted in the original multi-contrast image data. These feature maps may depict the spatial distribution or spatial patterns of features, statistics, or other parameters associated with estimated tissue properties. As another example, the tissue feature data may include classification maps that indicate the local probability for a particular classification (i.e., the probability that a voxel belongs to a particular class), such as whether a region of a tissue corresponds to a particular lesion type.

The tissue feature data generated by inputting the compact signal feature map data to the trained machine learning algorithm(s) can then be displayed to a user, stored for later use or further processing, or both, as indicated at step 310. In some instances, the tissue feature data can be overlaid with the original multi-contrast image data and displayed to the user. For instance, classifications or estimated tissue properties can be displayed as an overlay in the multi-contrast images, or as a separate display element or image.

Referring now to FIG. 4, a flowchart is illustrated as setting forth the steps of an example method for training one or more machine learning algorithms on training data, such that the one or more machine learning algorithms are trained to receive input as compact signal feature map data extracted from multi-contract image data in order to generate output as tissue feature data that quantify, classify, or otherwise characterize one or more tissue properties of tissues depicted in multi-contrast image data.

In general, the machine learning algorithm(s) can implement any number of different model architectures or algorithm types. For instance, the machine learning algorithm(s) could implement a convolutional neural network, a residual neural network, or other artificial neural network. In some instances, the neural network(s) may implement deep learning. Alternatively, the neural network(s) could be replaced with other suitable machine learning algorithms, such as those based on supervised learning, unsupervised learning, deep learning, ensemble learning, dimensionality reduction, and so on.

The method includes accessing training data with a computer system, as indicated at step 402. Accessing the training data may include retrieving such data from a memory or other suitable data storage device or medium. Alternatively, accessing the training data may include acquiring such data with an MRI system and transferring or otherwise communicating the data to the computer system, which may be a part of the MRI system. Additionally or alternatively, accessing the training data may include generating training data from magnetic resonance imaging data (e.g., multi-contrast image data).

In general, the training data can include multi-contrast image data, compact signal feature data extracted from the multi-contract image data, and tissue feature data associated with tissues depicted in the multi-contrast image data.

Accessing the training data can include assembling training data from multi-contrast image data and/or compact signal feature data using a computer system. This step may include assembling the training data into an appropriate data structure on which the machine learning algorithm can be trained. Assembling the training data may include assembling multi-contrast image data and/or compact signal feature data, segmented multi-contrast image data and/or compact signal feature data, and other relevant data. For instance, assembling the training data may include generating labeled data and including the labeled data in the training data. Labeled data may include multi-contrast image data and/or compact signal feature data, segmented multi-contrast image data and/or compact signal feature data, or other relevant data that have been labeled as belonging to, or otherwise being associated with, one or more different classifications or categories. For instance, labeled data may include multi-contrast image data and/or compact signal feature data that have been labeled based on different tissue types, tissue properties, lesion types, or other tissue features depicted in the images. The labeled data may include labeling all data within a field-of-view of the multi-contrast image data and/or compact signal feature data, or may include labeling only those data in one or more regions-of-interest within the multi-contrast image data and/or compact signal feature data. The labeled data may include data that are classified on a voxel-by-voxel basis, or a regional or larger volume basis.

One or more machine learning algorithms are trained on the training data, as indicated at step 404. In general, the machine learning algorithms can be trained by optimizing model parameters (e.g., weights, biases, or both) based on minimizing a loss function. As one non-limiting example, the loss function may be a mean squared error loss function.

Training a machine learning algorithm may include initializing the machine learning algorithm, such as by computing, estimating, or otherwise selecting initial model parameters (e.g., weights, biases, or both). Training data can then be input to the initialized machine learning algorithm, generating output as tissue feature data. The quality of the tissue feature data can then be evaluated, such as by passing the tissue feature data to the loss function to compute an error. The current neural network can then be updated based on the calculated error (e.g., using backpropagation methods based on the calculated error). For instance, the current machine learning algorithm can be updated by updating the model parameters (e.g., weights, biases, or both) in order to minimize the loss according to the loss function. When the error has been minimized (e.g., by determining whether an error threshold or other stopping criterion has been satisfied), the current machine learning algorithm and its associated model parameters represent the trained machine learning algorithm.

The one or more trained machine learning algorithms are then stored for later use, as indicated at step 406. Storing the machine learning algorithm(s) may include storing model parameters (e.g., weights, biases, or both), which have been computed or otherwise estimated by training the machine learning algorithm(s) on the training data. Storing the trained machine learning algorithm(s) may also include storing the particular model architecture to be implemented. For instance, data pertaining to the layers in the model architecture (e.g., number of layers, type of layers, ordering of layers, connections between layers, hyperparameters for layers) may be stored.

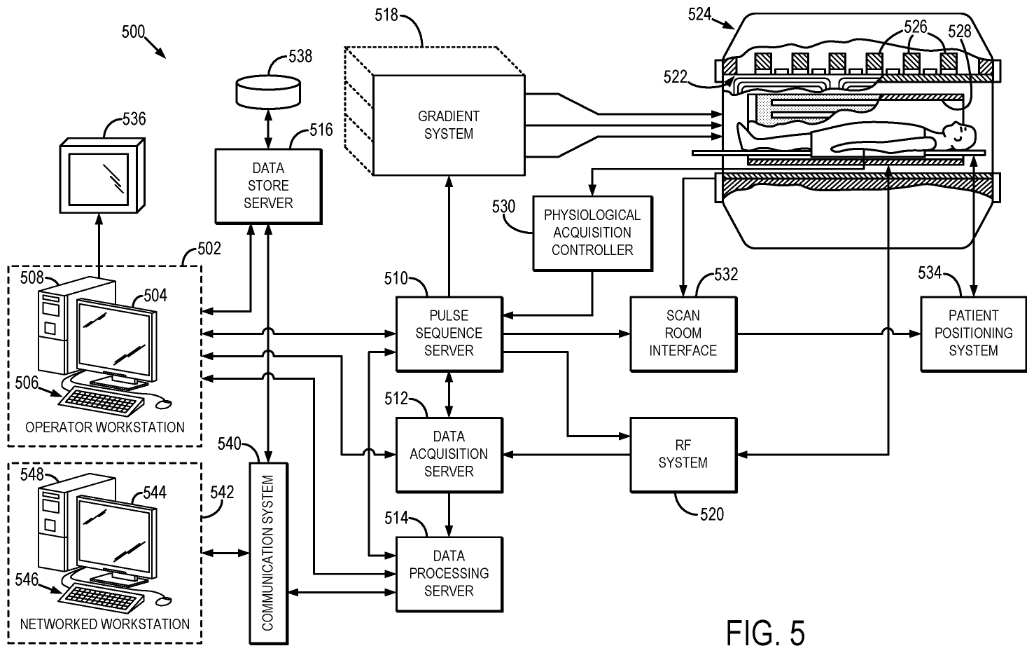

Referring particularly now to FIG. 5, an example of an MRI system 500 that can implement the methods described here is illustrated. The MRI system 500 includes an operator workstation 502 that may include a display 504, one or more input devices 506 (e.g., a keyboard, a mouse), and a processor 508. The processor 508 may include a commercially available programmable machine running a commercially available operating system. The operator workstation 502 provides an operator interface that facilitates entering scan parameters into the MRI system 500. The operator workstation 502 may be coupled to different servers, including, for example, a pulse sequence server 510, a data acquisition server 512, a data processing server 514, and a data store server 516. The operator workstation 502 and the servers 510, 512, 514, and 516 may be connected via a communication system 540, which may include wired or wireless network connections.

The pulse sequence server 510 functions in response to instructions provided by the operator workstation 502 to operate a gradient system 518 and a radiofrequency (“RF”) system 520. Gradient waveforms for performing a prescribed scan are produced and applied to the gradient system 518, which then excites gradient coils in an assembly 522 to produce the magnetic field gradients Gₓ, G_{y}, and G_{z} that are used for spatially encoding magnetic resonance signals. The gradient coil assembly 522 forms part of a magnet assembly 524 that includes a polarizing magnet 526 and a whole-body RF coil 528.

RF waveforms are applied by the RF system 520 to the RF coil 528, or a separate local coil to perform the prescribed magnetic resonance pulse sequence. Responsive magnetic resonance signals detected by the RF coil 528, or a separate local coil, are received by the RF system 520. The responsive magnetic resonance signals may be amplified, demodulated, filtered, and digitized under direction of commands produced by the pulse sequence server 510. The RF system 520 includes an RF transmitter for producing a wide variety of RF pulses used in MRI pulse sequences. The RF transmitter is responsive to the prescribed scan and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. An RF receiver channel includes an RF preamplifier that amplifies the magnetic resonance signal received by the coil 528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 510 may receive patient data from a physiological acquisition controller 530. By way of example, the physiological acquisition controller 530 may receive signals from a number of different sensors connected to the patient, including electrocardiograph (“ECG”) signals from electrodes, or respiratory signals from a respiratory bellows or other respiratory monitoring devices. These signals may be used by the pulse sequence server 510 to synchronize, or “gate,” the performance of the scan with the subject's heart beat or respiration.

The pulse sequence server 510 may also connect to a scan room interface circuit 532 that receives signals from various sensors associated with the condition of the patient and the magnet system. Through the scan room interface circuit 532, a patient positioning system 534 can receive commands to move the patient to desired positions during the scan.

The digitized magnetic resonance signal samples produced by the RF system 520 are received by the data acquisition server 512. The data acquisition server 512 operates in response to instructions downloaded from the operator workstation 502 to receive the real-time magnetic resonance data and provide buffer storage, so that data is not lost by data overrun. In some scans, the data acquisition server 512 passes the acquired magnetic resonance data to the data processor server 514. In scans that require information derived from acquired magnetic resonance data to control the further performance of the scan, the data acquisition server 512 may be programmed to produce such information and convey it to the pulse sequence server 510. For example, during pre-scans, magnetic resonance data may be acquired and used to calibrate the pulse sequence performed by the pulse sequence server 510. As another example, navigator signals may be acquired and used to adjust the operating parameters of the RF system 520 or the gradient system 518, or to control the view order in which k-space is sampled. In still another example, the data acquisition server 512 may also process magnetic resonance signals used to detect the arrival of a contrast agent in a magnetic resonance angiography (“MRA”) scan. For example, the data acquisition server 512 may acquire magnetic resonance data and processes it in real-time to produce information that is used to control the scan.

The data processing server 514 receives magnetic resonance data from the data acquisition server 512 and processes the magnetic resonance data in accordance with instructions provided by the operator workstation 502. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 514 are conveyed back to the operator workstation 502 for storage. Real-time images may be stored in a data base memory cache, from which they may be output to operator display 502 or a display 536. Batch mode images or selected real time images may be stored in a host database on disc storage 538. When such images have been reconstructed and transferred to storage, the data processing server 514 may notify the data store server 516 on the operator workstation 502. The operator workstation 502 may be used by an operator to archive the images, produce films, or send the images via a network to other facilities.

The MRI system 500 may also include one or more networked workstations 542. For example, a networked workstation 542 may include a display 544, one or more input devices 546 (e.g., a keyboard, a mouse), and a processor 548. The networked workstation 542 may be located within the same facility as the operator workstation 502, or in a different facility, such as a different healthcare institution or clinic.

The networked workstation 542 may gain remote access to the data processing server 514 or data store server 516 via the communication system 540. Accordingly, multiple networked workstations 542 may have access to the data processing server 514 and the data store server 516. In this manner, magnetic resonance data, reconstructed images, or other data may be exchanged between the data processing server 514 or the data store server 516 and the networked workstations 542, such that the data or images may be remotely processed by a networked workstation 542.

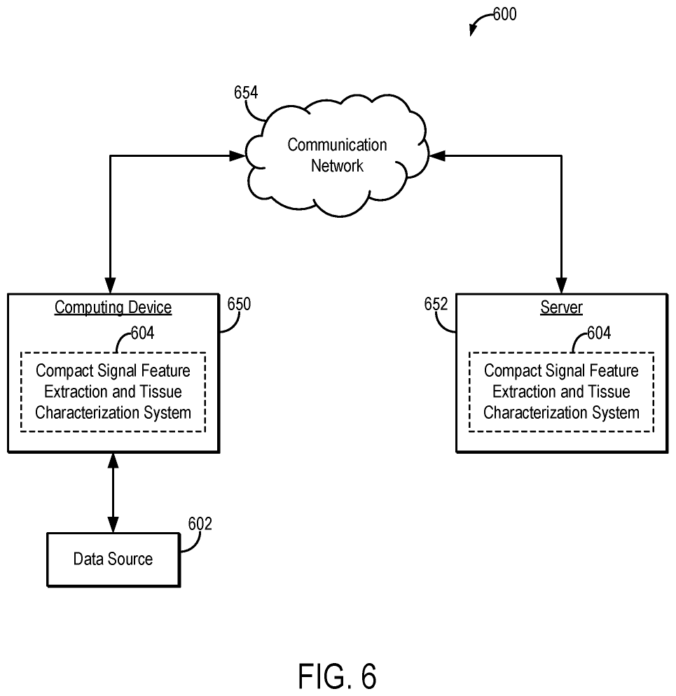

Referring now to FIG. 6, an example of a system 600 for extracting compact signal feature data from multi-contrast image data and applying those compact signal feature data to one or more machine learning algorithms to generate tissue feature data that quantifies tissue properties, classifies tissues, or other characterizes tissues depicted in the multi-contrast image data in accordance with some embodiments of the systems and methods described in the present disclosure is shown. As shown in FIG. 6, a computing device 650 can receive one or more types of data (e.g., images, k-space data, k-t space data) from data source 602, which may be a magnetic resonance imaging data source. In some embodiments, computing device 650 can execute at least a portion of a compact signal feature extraction and tissue characterization system 604 to extract compact signal feature data from multi-contrast image data received from the data source 602 and to apply those compact signal feature data to one or more machine learning algorithms to generate tissue feature data that quantifies tissue properties, classifies tissues, or other characterizes tissues depicted in the multi-contrast image data.

Additionally or alternatively, in some embodiments, the computing device 650 can communicate information about data received from the data source 602 to a server 652 over a communication network 654, which can execute at least a portion of the compact signal feature extraction and tissue characterization system 604. In such embodiments, the server 652 can return information to the computing device 650 (and/or any other suitable computing device) indicative of an output of the compact signal feature extraction and tissue characterization system 604.

In some embodiments, computing device 650 and/or server 652 can be any suitable computing device or combination of devices, such as a desktop computer, a laptop computer, a smartphone, a tablet computer, a wearable computer, a server computer, a virtual machine being executed by a physical computing device, and so on. The computing device 650 and/or server 652 can also reconstruct images from the data. For example, the computing device 650 and/or server 652 can reconstruct images from k-space and/or k-t space data received from the data source 602.

In some embodiments, data source 602 can be any suitable source of data (e.g., k-space data, k-t space data, images reconstructed from k-space and/or k-t space data), such as an MRI system, another computing device (e.g., a server storing k-space, k-t space data, and/or reconstructed images), and so on. In some embodiments, data source 602 can be local to computing device 650. For example, data source 602 can be incorporated with computing device 650 (e.g., computing device 650 can be configured as part of a device for measuring, recording, estimating, acquiring, or otherwise collecting or storing data). As another example, data source 602 can be connected to computing device 650 by a cable, a direct wireless link, and so on. Additionally or alternatively, in some embodiments, data source 602 can be located locally and/or remotely from computing device 650, and can communicate data to computing device 650 (and/or server 652) via a communication network (e.g., communication network 654).

In some embodiments, communication network 654 can be any suitable communication network or combination of communication networks. For example, communication network 654 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 654 can be a local area network, a wide area network, a public network (e.g., the Internet), a private or semi-private network (e.g., a corporate or university intranet), any other suitable type of network, or any suitable combination of networks. Communications links shown in FIG. 6 can each be any suitable communications link or combination of communications links, such as wired links, fiber optic links, Wi-Fi links, Bluetooth links, cellular links, and so on.

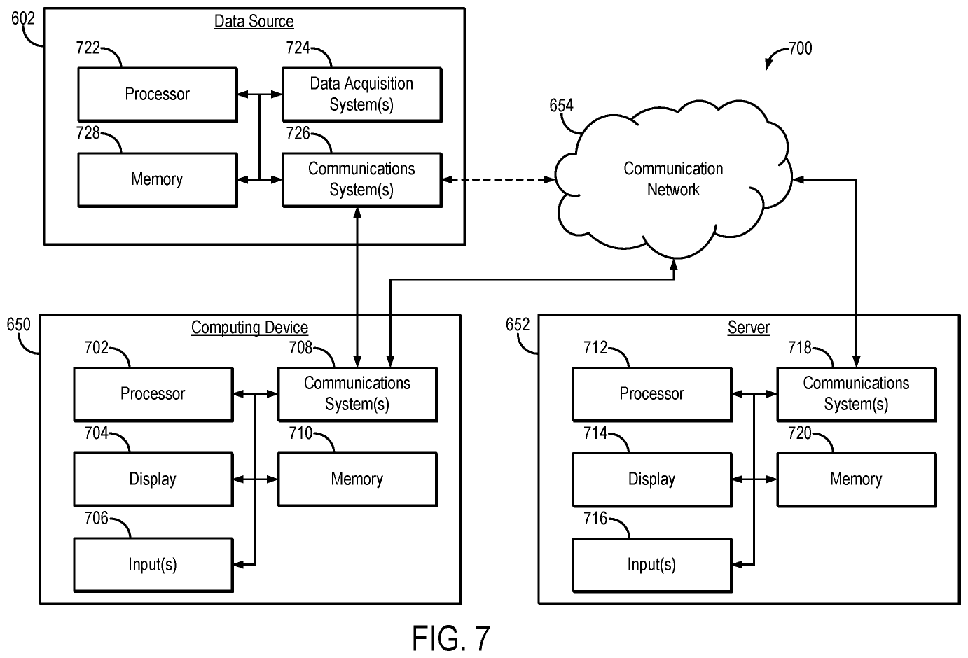

Referring now to FIG. 7, an example of hardware 700 that can be used to implement data source 602, computing device 650, and server 652 in accordance with some embodiments of the systems and methods described in the present disclosure is shown.

As shown in FIG. 7, in some embodiments, computing device 650 can include a processor 702, a display 704, one or more inputs 706, one or more communication systems 708, and/or memory 710. In some embodiments, processor 702 can be any suitable hardware processor or combination of processors, such as a central processing unit (“CPU”), a graphics processing unit (“GPU”), and so on. In some embodiments, display 704 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 706 can include any suitable input devices and/or sensors that can be used to receive user input, such as a keyboard, a mouse, a touchscreen, a microphone, and so on.

In some embodiments, communications systems 708 can include any suitable hardware, firmware, and/or software for communicating information over communication network 654 and/or any other suitable communication networks. For example, communications systems 708 can include one or more transceivers, one or more communication chips and/or chip sets, and so on. In a more particular example, communications systems 708 can include hardware, firmware, and/or software that can be used to establish a Wi-Fi connection, a Bluetooth connection, a cellular connection, an Ethernet connection, and so on.

In some embodiments, memory 710 can include any suitable storage device or devices that can be used to store instructions, values, data, or the like, that can be used, for example, by processor 702 to present content using display 704, to communicate with server 652 via communications system(s) 708, and so on. Memory 710 can include any suitable volatile memory, non-volatile memory, storage, or any suitable combination thereof. For example, memory 710 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 710 can have encoded thereon, or otherwise stored therein, a computer program for controlling operation of computing device 650. In such embodiments, processor 702 can execute at least a portion of the computer program to present content (e.g., images, user interfaces, graphics, tables), receive content from server 652, transmit information to server 652, and so on. For example, the processor 702 and the memory 710 can be configured to perform the methods described herein (e.g., the method of FIG. 1, the method of FIG. 3, the method of FIG. 4).

In some embodiments, server 652 can include a processor 712, a display 714, one or more inputs 716, one or more communications systems 718, and/or memory 720. In some embodiments, processor 712 can be any suitable hardware processor or combination of processors, such as a CPU, a GPU, and so on. In some embodiments, display 714 can include any suitable display devices, such as an LCD screen, LED display, OLED display, electrophoretic display, a computer monitor, a touchscreen, a television, and so on. In some embodiments, inputs 716 can include any suitable input devices and/or sensors that can be used to receive user input, such as a keyboard, a mouse, a touchscreen, a microphone, and so on.

In some embodiments, communications systems 718 can include any suitable hardware, firmware, and/or software for communicating information over communication network 654 and/or any other suitable communication networks. For example, communications systems 718 can include one or more transceivers, one or more communication chips and/or chip sets, and so on. In a more particular example, communications systems 718 can include hardware, firmware, and/or software that can be used to establish a Wi-Fi connection, a Bluetooth connection, a cellular connection, an Ethernet connection, and so on.

In some embodiments, memory 720 can include any suitable storage device or devices that can be used to store instructions, values, data, or the like, that can be used, for example, by processor 712 to present content using display 714, to communicate with one or more computing devices 650, and so on. Memory 720 can include any suitable volatile memory, non-volatile memory, storage, or any suitable combination thereof. For example, memory 720 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 720 can have encoded thereon a server program for controlling operation of server 652. In such embodiments, processor 712 can execute at least a portion of the server program to transmit information and/or content (e.g., data, images, a user interface) to one or more computing devices 650, receive information and/or content from one or more computing devices 650, receive instructions from one or more devices (e.g., a personal computer, a laptop computer, a tablet computer, a smartphone), and so on.

In some embodiments, the server 652 is configured to perform the methods described in the present disclosure. For example, the processor 712 and memory 720 can be configured to perform the methods described herein (e.g., the method of FIG. 1, the method of FIG. 3, the method of FIG. 4).

In some embodiments, data source 602 can include a processor 722, one or more data acquisition systems 724, one or more communications systems 726, and/or memory 728. In some embodiments, processor 722 can be any suitable hardware processor or combination of processors, such as a CPU, a GPU, and so on. In some embodiments, the one or more data acquisition systems 724 are generally configured to acquire data, images, or both, and can include an MRI system. Additionally or alternatively, in some embodiments, the one or more data acquisition systems 724 can include any suitable hardware, firmware, and/or software for coupling to and/or controlling operations of an MRI system. In some embodiments, one or more portions of the data acquisition system(s) 724 can be removable and/or replaceable.

Note that, although not shown, data source 602 can include any suitable inputs and/or outputs. For example, data source 602 can include input devices and/or sensors that can be used to receive user input, such as a keyboard, a mouse, a touchscreen, a microphone, a trackpad, a trackball, and so on. As another example, data source 602 can include any suitable display devices, such as an LCD screen, an LED display, an OLED display, an electrophoretic display, a computer monitor, a touchscreen, a television, etc., one or more speakers, and so on.

In some embodiments, communications systems 726 can include any suitable hardware, firmware, and/or software for communicating information to computing device 650 (and, in some embodiments, over communication network 654 and/or any other suitable communication networks). For example, communications systems 726 can include one or more transceivers, one or more communication chips and/or chip sets, and so on. In a more particular example, communications systems 726 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 728 can include any suitable storage device or devices that can be used to store instructions, values, data, or the like, that can be used, for example, by processor 722 to control the one or more data acquisition systems 724, and/or receive data from the one or more data acquisition systems 724; to generate images from data; present content (e.g., images, a user interface) using a display; communicate with one or more computing devices 650; and so on. Memory 728 can include any suitable volatile memory, non-volatile memory, storage, or any suitable combination thereof. For example, memory 728 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 728 can have encoded thereon, or otherwise stored therein, a program for controlling operation of data source 702. In such embodiments, processor 722 can execute at least a portion of the program to generate images, transmit information and/or content (e.g., data, images) to one or more computing devices 650, receive information and/or content from one or more computing devices 650, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

The present disclosure has described one or more preferred embodiments, and it should be appreciated that many equivalents, alternatives, variations, and modifications, aside from those expressly stated, are possible and within the scope of the invention.

1. A method for generating compact signal feature maps from multi-contrast magnetic resonance images, the method comprising:
(a) accessing multi-contrast image data with a computer system, wherein the multi-contrast image data comprise a plurality of magnetic resonance images acquired with a magnetic resonance imaging (MRI) system from a subject, wherein the plurality of magnetic resonance images depict multiple different contrast weightings;
(b) generating subspace bases from prior signal data using the computer system;
(c) reconstructing coefficient maps for the subspace bases using a subspace reconstruction framework implemented with the computer system, wherein the subspace reconstruction framework takes as inputs the subspace bases and the multi-contrast image data; and
(d) storing the coefficient maps as compact signal feature data using the computer system, wherein the compact signal feature data depict similar information as the multi-contrast image data with significantly reduced degrees of freedom relative to the multi-contrast image data.

2. The method of claim 1, wherein the prior signal data comprise previously acquired multi-contrast image data.

3. The method of claim 1, wherein the prior signal data comprise simulated multi-contrast image data.

4. The method of claim 1, wherein generating the subspace bases from the prior signal data comprises applying a principal component analysis to the prior signal data and retaining a number of principal components as the subspace bases.

5. The method of claim 1, wherein generating the subspace bases from the prior signal data comprises applying an independent component analysis to the prior signal data and retaining a number of components as the subspace bases.

6. The method of claim 1, wherein the multiple different contrast weightings include at least two of T1-weighting, T2-weighting, T2*-weighting, or fluid attenuation inversion recovery (FLAIR) weighting.

7. The method of claim 1, further comprising:
accessing a machine learning algorithm with the computer system, wherein the machine learning algorithm has been trained on training data to generate tissue feature data based on compact signal feature map data; and
generating tissue feature data using the computer system to apply the compact signal feature data extracted from the multi-contrast image data to the machine learning algorithm, generating output as tissue feature data indicative of at least one tissue property of a tissue depicted in the multi-contrast image data.

8. The method of claim 7, wherein the tissue feature data comprise tissue classification data that indicate a classification of the tissue depicted in the multi-contrast image data based on the at least one tissue property.

9. The method of claim 7, wherein the tissue feature data indicate a detection of a tissue feature of the tissue depicted in the multi-contrast image data based on the at least one tissue property.

10. The method of claim 7, wherein the machine learning algorithm is a supervised learning-based machine learning algorithm.

11. The method of claim 7, wherein the machine learning algorithm is an unsupervised learning-based machine learning algorithm.

12. The method of claim 7, further comprising displaying the multi-contrast image data to a user together with the tissue feature data.
